(19) United States
(12) Patent Application Publication
(10) Pub. No.: US 2010/0123472 A1
(43) Pub. Date: May 20, 2010

(54) Probe card and test method using the same

(75) Inventor: Masakatsu Saijou, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/591,433

(22) Filed: Nov. 19, 2009

(30) Foreign Application Priority Data
Nov. 20, 2008 (JP) 2008-296771

(51) Int. Cl. G01R 31/02; G01R 31/26

(52) U.S. Cl. 324/754; 324/765

(57) ABSTRACT

A test method of a semiconductor device using a probe card includes the steps of performing a self-test and performing a normal-mode test. In the self-test, a quality of the semiconductor device is examined while connecting the first probe needle to the first signal terminal of the semiconductor device, and using the tester connected to the connection terminal. In the normal-mode test, a quality of the semiconductor device is examined while connecting the second probe needle to the second signal terminal of the semiconductor device, and using the tester connected to the connection terminal.

### BACKGROUND OF THE INVENTION

The present invention relates to a probe card used for testing a semiconductor device, and also relates to a test method for examining a quality of the semiconductor devices using the probe card.

Generally, a probe card is used together with a tester for examining the quality of the semiconductor devices formed on a semiconductor wafer (see, for example, Patent Document No. 1). The probe card has probe needles for contact with signal terminals of the semiconductor devices, connection terminals connected to channels of the tester, and connection wirings connecting the probe needles and the connection terminals.

In order to shorten a time required for examining the quality of semiconductor devices formed on a wafer, it is preferred to test a large number of semiconductor devices at the same time. The number of semiconductor devices that can be tested at the same time generally depends on a ratio of the number N_{T} of channels of the tester to the number N_{D} of signal terminals of each semiconductor device, which is expressed as N_{T}/N_{D} (N_{T}÷N_{D}).

As a measure to increase the number of semiconductor devices that can be tested at the same time, a self-test is generally performed by means of Built-In Self-test (BIST) circuits mounted on the semiconductor devices as special features. The BIST circuit has a function (i.e., a self-test function) to test an internal circuit of the semiconductor device. The semiconductor device has a first I/O (input/output) terminal used for the self-test, and a second I/O terminal used for a normal-mode test.

The conventional probe card connects the first I/O terminals of the semiconductor devices to the channels of the tester. Using the probe card, the tester sends signals to the BIST circuits of the respective semiconductor devices, so that the BIST circuits perform the self-test of the internal circuits of the semiconductor devices (see, for example, Patent Documents No. 2 and 3).

Patent Document No. 1: Japanese Laid-Open Patent Publication No. 2003-100820

Patent Document No. 2: Japanese Laid-Open Patent Publication No. 2005-209239

Patent Document No. 3: Japanese Laid-Open Patent Publication No. 2008-217880

In this regard, if any one of the semiconductor devices is found to be defective in the self-test, it is necessary to perform a normal-mode test to thereby determine whether the problem is in the internal circuit or in the BIST circuit. However, the conventional probe card does not connect the second I/O terminals of the semiconductor devices to the channels of the tester. Therefore, it is necessary to use an exclusive probe card for the normal-mode test, which connects the second I/O terminals of the semiconductor devices to the channels of the tester. However, it is inconvenient to use two types of probe cards.

### SUMMARY OF THE INVENTION

The present invention is intended to solve the above described problems, and an object of the present invention is to enhance convenience in a test for examining a quality of a semiconductor device.

According to an aspect of the present invention, there is provided a test method of a semiconductor device using a probe card. The semiconductor device includes an internal circuit, a self-test circuit having a function to test the internal circuit, a first signal terminal for a self-test of the internal circuit, and a second signal terminal for a normal-mode test of the internal circuit.

The probe card includes a probe card substrate, a first probe needle provided on the probe card substrate for contact with the first signal terminal of the semiconductor device, a second probe needle provided on the probe card substrate for contact with the second signal terminal of the semiconductor device, a connection terminal provided on the probe card substrate and being connectable to a tester, a first connection wiring provided on the probe card substrate so as to connect the first probe needle to the connection terminal, and a second connection wiring provided on the probe card substrate so as to connect the second probe needle to the first connection wiring.

The test method includes the steps of performing a self-test to thereby examine a quality of the semiconductor device by connecting the first probe needle to the first signal terminal of the semiconductor device and by using the tester connected to the connection terminal, and performing a normal-mode test to thereby examine a quality of the semiconductor device by connecting the second probe needle to the second signal terminal of the semiconductor device and by using the tester connected to the connection terminal that is connected to the second signal terminal via the first connection wiring and the second connection wiring.

Since both of the self-test and the normal-mode test can be performed using the same probe card, it is not necessary to use an exclusive probe card for the normal-mode test. Therefore, it becomes possible to enhance convenience in the test for examining the quality of the semiconductor device.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

In the attached drawings:

FIG. 1 shows a test apparatus for testing semiconductor devices using a probe card according to the first embodiment of the present invention;

FIG. 2 is a schematic view showing second connection wirings of the probe card shown in FIG. 1;

FIG. 3A is plan view showing the probe card according to the first embodiment;

FIG. 3B is a side view showing the test apparatus according to the first embodiment;

FIG. 4 shows an example of the test apparatus during a normal-mode test according to the first embodiment;

FIG. 5 is a side view showing a test apparatus for testing semiconductor devices using a probe card according to the second embodiment of the present invention, and

FIG. 6 shows a test apparatus for testing semiconductor devices using a probe card of a comparison example.

### DETAILED DESCRIPTION OF THE PREFERRED EMBODIMENT

Hereinafter, embodiments of the present invention will be described with reference to the attached drawings.

### FIRST EMBODIMENT

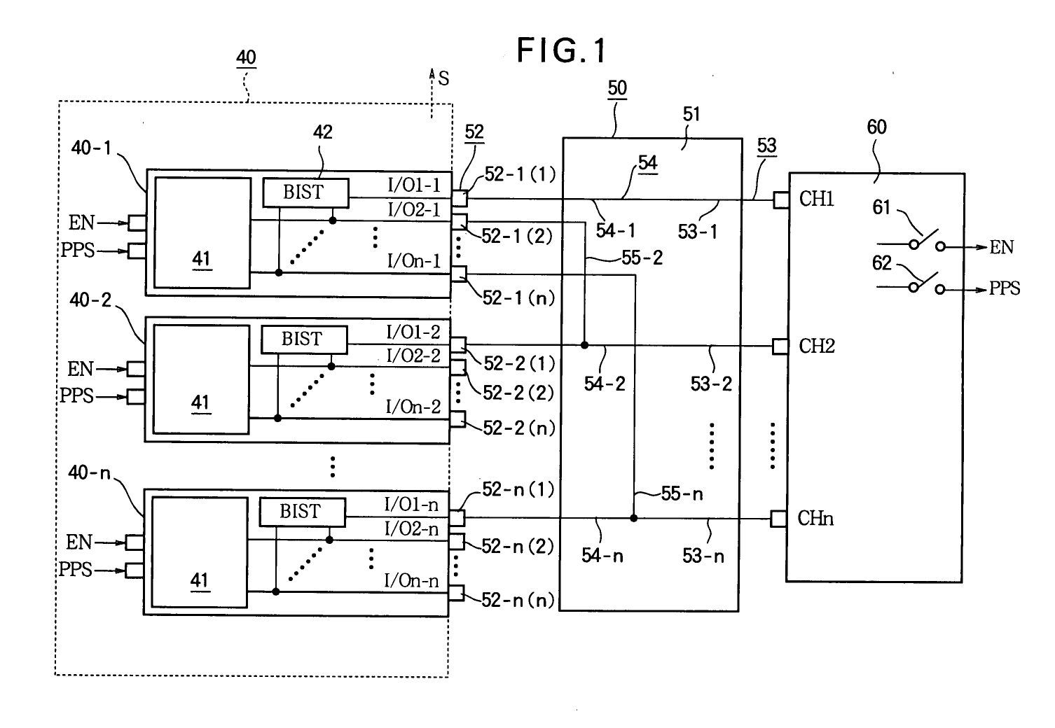

FIG. 1 shows a test apparatus for testing semiconductor devices using a probe card according to the first embodiment of the present invention.

The test apparatus includes a probe card 50 and a tester 60 for testing a plurality of semiconductor devices 40-1 to 40-n (i.e., test objects) formed on a wafer 40.

The semiconductor devices 40-1 to 40-n includes internal circuits 41 (such as semiconductor memories), BIST circuits 42 as special features having a function (i.e., self-test function) to test the internal circuits 41, first I/O terminals (i.e., first signal terminals) 1-1, 1-2 . . . 1-n connected to the BIST circuits 42 and used for a self-test of the internal circuits 41, second I/O terminals (i.e., second signal terminals) 2-1 to n-1, 2-2 to 2-n . . . 3-n to n-n connected to the internal circuits and used for a normal-mode test of the internal circuits 41. The semiconductor devices 40-1 to 40-n perform predetermined device operations upon receiving power voltages PPS and enable signals EN (required for performing the operations) sent from the tester 60. The BIST circuits 42 of the respective semiconductor devices 40-1 to 40-n are configured to automatically test the internal circuits 41 upon receiving test signals from the tester 60 via the first I/O terminals 1-1 to 1-n. The BIST circuits 42 can be composed of various kinds of circuits such as those disclosed in the Patent Document No. 2 or 3.

The probe card 50 includes a probe card substrate 51, and a plurality of probe needles 52 (52-1, 52-2 . . . 52-n) provided on the probe card substrate 51 for contact with the I/O terminals of the semiconductor devices 40-1 to 40-n.

More specifically, the probe needles 52-1 include a first probe needle 52-1(1) for contact with the first I/O terminal 1-1 of the semiconductor device 40-1, and second probe needles 52-1(2) to 52-1(n) respectively for contact with the second I/O terminals 2-1 to n-1 of the semiconductor device 40-1. The probe needles 52-2 include a first probe needle 52-2(1) for contact with the first I/O terminal 1-2 of the semiconductor device 40-2, and second probe needles 52-2(2) to 52-2(n) respectively for contact with the second I/O terminals 2-2 to n-2 of the semiconductor device 40-2. Similarly, the probe needles 52-n include a first probe needle 52-n(1) for contact with the first I/O terminal 1-n of the semiconductor device 40-n, and second probe needles 52-n(2) to 52-n(n) respectively for contact with the second I/O terminals 2-n to n-n of the semiconductor device 40-n.

The probe card 50 further includes a plurality of connection terminals 53 (53-1, 53-2 . . . 53-n) provided on the probe card substrate 51 so as to be connectable to channels of the tester 60. The probe card 50 further includes a plurality of first connection wirings 54 (54-1, 54-2 . . . 54-n) that connect respective probe needles 52-1(1) to 52-n(1) respectively to the connection terminals 53-1 to 53-n.

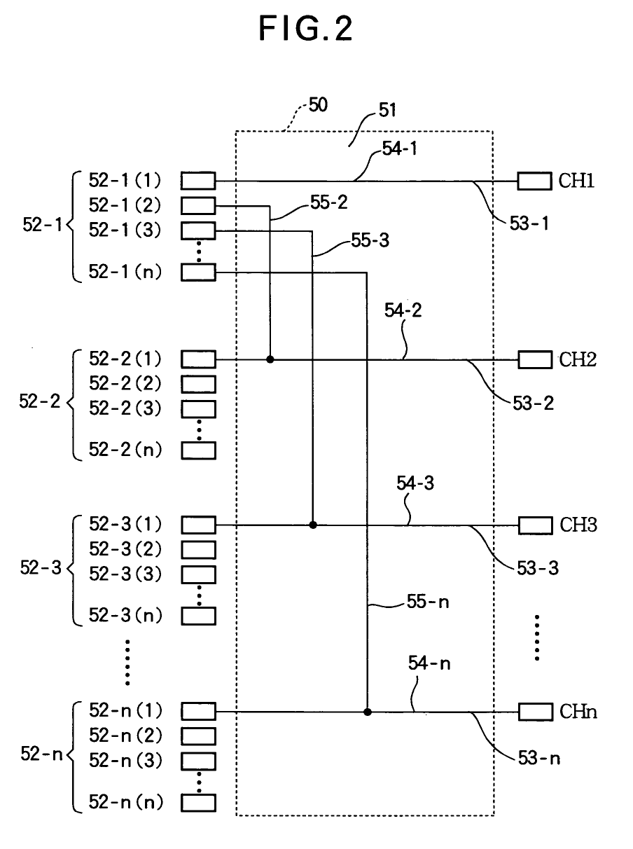

FIG. 2 is a schematic view showing second connection wirings (in this example, jumper cables) connecting the probe needles 52-1(2) to 52-1(n) to the first connection wirings 54-2 to 54-n. As shown in FIG. 2, a jumper cable 55-2 is provided on the probe card substrate 51 so as to connect the probe needle 52-1(2) to the first connection wiring 54-2. A jumper cable 55-3 is provided on the probe card substrate 51 so as to connect the probe needle 52-1(3) to the first connection wiring 54-3. Similarly, a jumper cable 55-n is provided on the probe card substrate 51 so as to connect the probe needle 52-1(n) to the first connection wiring 54-n.

The tester 60 includes a switch 61 and a switch 62 that respectively output the enable signals EN and the power voltages PPS for operating the semiconductor devices 40-1 to 40-n. The tester 60 further includes a plurality of channels CH1 to CHn connectable to the connection terminals 53 (53-1 to 53-n) of the probe card 50. The tester 60 outputs the enable signals EN and the power voltages PPS to the respective semiconductor devices 40-1 to 40-n, and outputs test signals via the channel CH1 to CHn according to a test pattern. Further, the tester 60 receives output signals from the first I/O terminals 1-1 to 1-n of the semiconductor devices 40-1 to 40-n, compares the output signals with expectation values, and examines the quality of the semiconductor devices 40-1 to 40-n.

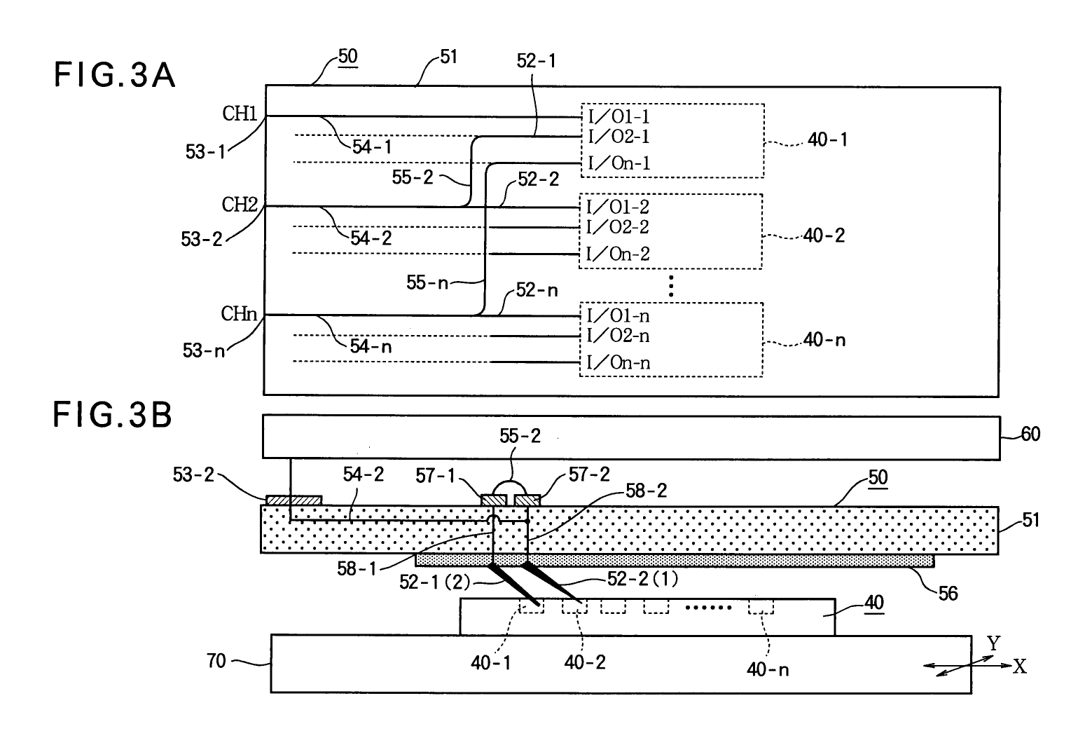

FIG. 3A is a plan view of the probe card 50 shown in FIG. 1. FIG. 3B is a side view of the test apparatus for testing the semiconductor devices 40-1 to 40-n shown in FIG. 1.

The test apparatus includes a stage 70 on which the wafer 40 with the semiconductor devices 10-1 to 10-n is placed. The stage 70 is disposed below the probe card 50 mounted to the test apparatus. The stage 70 is movable relative to the probe card 50 in directions of X-axis and Y-axis, i.e., in a horizontal plane.

The probe card 50 includes the above described probe card substrate 51, and a probe head 56 provided on a back surface (i.e., lower surface in FIG. 3B) of the probe card substrate 51. The above described probe needles 52 (52-1 to 52-n) are planted on the probe head 56, and extend downward from the probe head 56. The above described connection terminals 53 (53-1 to 53-n) are formed on a top surface (i.e. upper surface in FIG. 3B) of the probe card substrate 51 so as to be connectable to the tester 60.

The connection terminals 53 are formed of, for example, pogo seats.

The connection terminal 53-2 is connected to the probe needle 52-2(1) via the first connection wiring 54-2 and a penetration wiring 58-2 formed in the probe card substrate 51. The connection terminal 53-2 is also connected to the probe needle 52-1(2) via the first connection wiring 54-2, the penetration wiring 58-2, terminals 57-1 and 57-2 (formed on the top surface of the probe card substrate 51), the jumper cable 55-2, and a penetration wiring 58-1 formed in the probe card substrate 51. Similarly, although not shown in FIG. 3B, the connection terminal 53-n is connected to the probe needle 52-n(1), and is also connected to the probe needle 52-1(n).

<Test Method>

In the test for examining the quality of the semiconductor devices 40-1 to 40-n formed on the wafer 40, the self-test is first performed on the semiconductor devices 40-1 to 40-n, and then the normal-mode test is performed on the semiconductor device which has been found to be defective in the self-test, in order to determine a defective part of the semiconductor device.

<Self-Test>

First, the wafer 40 is placed on the stage 70. Then, the stage 70 is moved horizontally so as to position the semiconductor devices 40-1 to 40-n (i.e., test objects) with respect to the probe card 50. Then, the probe needles 52-1(1) to 52-n(1) are brought into contact with the first I/O terminals 1-1 to 1-n of the semiconductor devices 40-1 to 40-n. The enable signals EN and the power voltages PPS are outputted from the switches 61 and 62 under control of a test program of the tester 60, so as to activate the semiconductor devices 40-1 to 40-n. Further, the test signals (for the self-test) are outputted from the channel CH1 to CHn according to the test program. The test signals are transmitted via the connection terminals 53-1 to 53-n, the first connection wirings 54-1 to 54-n and the probe needles 52-1(1) to 52-n(1), and are inputted to the BIST circuits 42 of the respective semiconductor devices 40-1 to 40-n via the first I/O terminals 1-1 to 1-n.

Then, the BIST circuits 42 of the respective semiconductor devices 40-1 to 40-n automatically perform the self-tests to examine the quality of the internal circuits 41. The results of the self-tests are outputted from the first I/O terminals 1-1 to 1-n, are transmitted via the probe needles 52-1(1) to 52-n(1), the first connection wirings 54-1 to 54-n, the connection terminals 53-1 to 53-n, and are inputted to the tester 60 via the channels CH1 to CHn.

If any of the semiconductor devices (for example, the semiconductor device 40-2) is found to be defective in the self-test, the normal-mode test is performed on the semiconductor device 40-2 as described below.

<Normal-Mode Test>

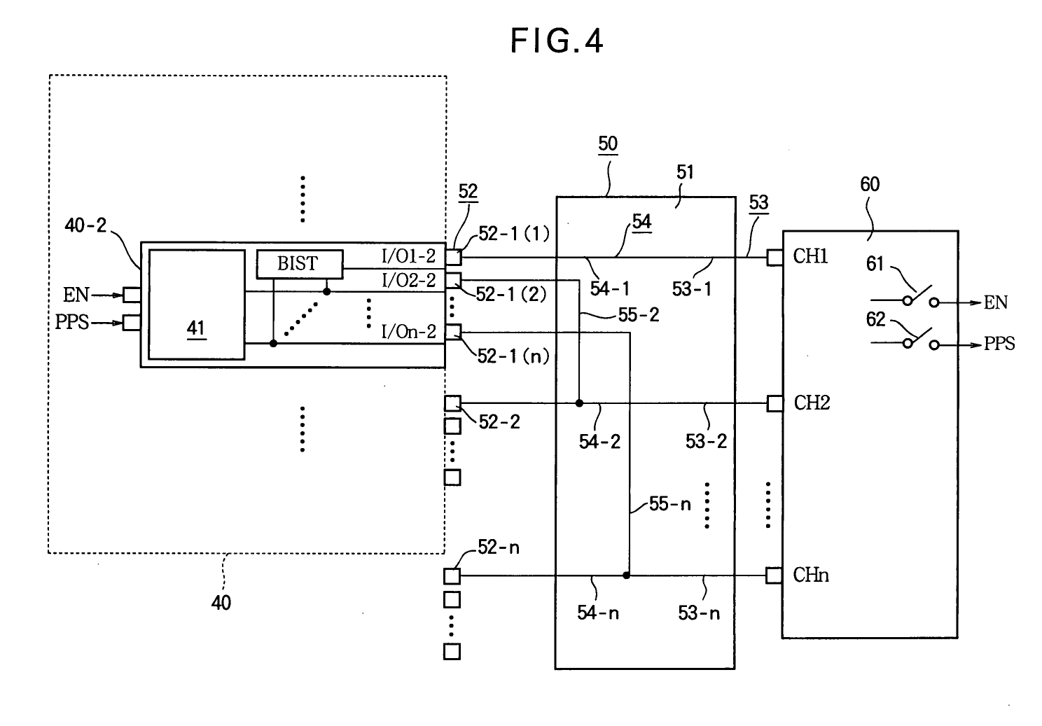

First, the probe needles 52-1(1) to 52-n(1) of the probe card 50 are separated from the first I/O terminals 1-1 to 1-n of the semiconductor devices 40-1 to 40-n. Then, the stage 70 is moved horizontally as shown by an arrow S in FIG. 1 so that the semiconductor device 40-2 (i.e., the test object) on the wafer 40 is aligned with the probe card 50. Then, the probe needles 52-1(1) to 52-1(n) of the probe card 50 are brought into contact with the I/O terminals 1-2 to n-2 of the semiconductor device 40-2 as shown in FIG. 4. In this state, the first I/O terminal 1-2 is connected to the channel CH1 of the tester via the probe needle 52-1(1), the first connection wiring 54-1 and the connection terminal 53-1. The second I/O terminal 2-2 is connected to the channel CH2 of the tester 60 via the probe needle 52-1(2), the jumper cable 55-2, the first connection wiring 54-2 and the connection terminal 53-2. Similarly, the second I/O terminal n-2 is connected to the channel CHn of the tester 60 via the probe needle 52-1(n), the jumper cable 55-n, the first connection wiring 54-n and the connection terminal 53-n.

The enable signal EN and the power voltage PPS are outputted from the switches 61 and 62 under control of a test program of the tester 60, so as to activate the semiconductor device 40-2. Further, the test signals (for the normal-mode test) are outputted from the channels CH2 to CHn according to the test program. In this state, the other devices 40-1, 40-3 to 40-n are excluded from test objects, and the enable signal EN and the power voltage PPS (required for the normal-mode test) are not input to these devices 40-1, 40-3 to 40-n. Therefore, interference between the signal outputted from the semiconductor device 40-2 with signals outputted from the semiconductor devices 40-1, 40-3 to 40-n can be prevented.

The test signal (for the normal-mode test) outputted from the channel CH2 is transmitted via the connection terminal 53-2, the first connection wiring 54-2 and the jumper cable 55-2 and the probe needle 52-1 (2) of the probe card 50, and is inputted to the internal circuit 41 of the semiconductor device 40-2 via the second I/O terminal 2-2. Similarly, the test signal. outputted from the channel CHn is transmitted via the connection terminal 53-n, the first connection wiring 54-n and the jumper cable 55-n and the probe needle 52-1(n) of the probe card 50, and is inputted to the internal circuit 41 of the semiconductor device 40-2 via the second I/O terminal n-2.

Based on the test signals, the internal circuit 41 of the semiconductor device 40-2 performs the normal-mode test. The result of the normal-mode test is outputted from the second I/O terminals 2-2 to n-2 of the semiconductor device 40-2. The signal (representing the result of the normal-mode test) outputted from the second I/O terminal 2-2 is transmitted via the probe needle 52-1 (2), the jumper cable 55-2, the first connection wiring 54-2 and the connection wiring 53-2 of the probe card 50, and is inputted into the tester 60 via the channel CH2. Similarly, the signal outputted from the second I/O terminal n-2 is transmitted via the probe needle 52-1 (n), the jumper cable 55-n, the first connection wiring 54-n and the connection wiring 53-n of the probe card 50, and is inputted into the tester 60 via the channel CHn. The tester 60 compared the signals (representing the result of the normal-mode test) input via the channels CH2 to CHn with the expectation values, and determines whether the internal circuit 41 is defective or not. Based on this result, analysis is performed to determine a defective part of the semiconductor device 40-2.

<Advantages>

According to the first embodiment of the present invention, the probe card 50 includes the first probe needles 52-1(1) to 52-n(1) for contact with the first I/O terminals 1-1 to 1-n, the second probe needles 52-1(2) to 52-n(n) for contact with the second I/O terminals 2-1 to n-n, the connection terminals 53-1 to 53-n connectable to the tester 60, the first connection wirings 54-1 to 54-n connecting the first probe needles 52-1(1) to 52-n(1) to the connection terminals 53-1 to 53-n, and the second connection wirings (i.e., jumper cables) 55-2 to 55-n connecting the second probe needles 52-1(2) to 52-n(n) to the first connection wirings 54-1 to 54-n. With such a configuration, it becomes possible to perform the self-test and the normal-mode test using the same probe card 50. In other words, it is not necessary to use an exclusive probe card for the normal-mode test (for connecting the second I/O terminals 2-1 to n-n of the semiconductor device 40-1 to 40-n to the channel CH2 to CHn of the tester 60).

Moreover, the self-test is first performed on the semiconductor devices 40-1 to 40-n, and then the normal-mode test is performed on the semiconductor device having been found to be defective in the self-test, using the same probe card 50. Therefore, it becomes possible to efficiently examine the quality of a large number of the semiconductor devices 40-1 to 40-n in a short time period.

### SECOND EMBODIMENT

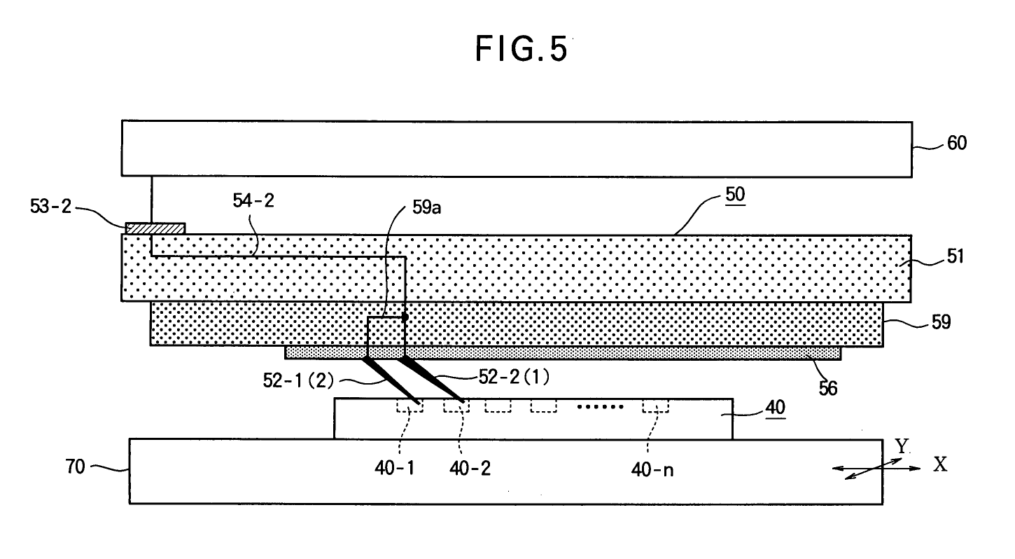

FIG. 5 is a side view showing a test apparatus for testing the semiconductor devices according to the second embodiment of the present invention. In FIG. 5, components that are the same as those of the first embodiment (FIG. 3B) are assigned the same reference numerals.

The test apparatus for testing the semiconductor devices according to the second embodiment includes a wiring conversion board 59 instead of the jumper cables 55-2 to 55-n (see FIG. 1) of the first embodiment. The wiring conversion board 59 is disposed between the probe card substrate 51 and the probe head 56. The wiring conversion board 59 is bonded to facing surfaces of the probe card substrate 51 and the probe head 56. A plurality of connection wirings 59a corresponding to the jumper cables 55-2 to 55-n (see FIG. 1) are provided inside the wiring conversion board 59.

The connection terminal 53-2 is connected to the probe needle 52-2(1) via the first connection wiring 54-2, as was described in the first embodiment. The connection terminal 53-2 is also connected to the probe needle 52-1(2) via the first connection wiring 54-2, the connection wiring 59a of the wiring conversion board 59. Similarly, although not shown in FIG. 5, the connection terminal 53-n is connected to the probe needle 52-n(1) and is also connected to the probe needle 52-1(n).

Other components of the second embodiment are the same as those of the first embodiment.

The self-test and the normal-mode test are performed as described in the first embodiment, and the same advantages as in the first embodiment can be obtained.

Moreover, according to the second embodiment, the wiring conversion substrate 59 is used instead of the jumper cables 55-2 to 55-n of the first embodiment. Therefore, the probe needles 52-1(2) to 52-1(n) can be connected to the first connection wirings 54-2 to 54-n by simply bonding the wiring conversion substrate 59 (that has been preliminarily formed) to the surfaces of the probe card substrate 51 and the probe head 56.

In the above described first and second embodiments, the tests of the semiconductor devices 40-1 to 40-n on the wafer 40 have been described. However, the present invention is also applicable to the test of the semiconductor devices which having been separated from the wafer and mounted to a socket (as assembly), a socket-mounting board or the like.

In the above described first and second embodiments, the jumper cables 55-2 to 55-n and the wiring conversion board 59 have been described as examples of the second connection wirings. However, it is also possible to employ other types of the second connection wirings.

Moreover, the test apparatus of the semiconductor device can be modified to have other structure or shape shown in the drawings. Further, the processed of the tests can be modified to other processes.

### COMPARISON EXAMPLE

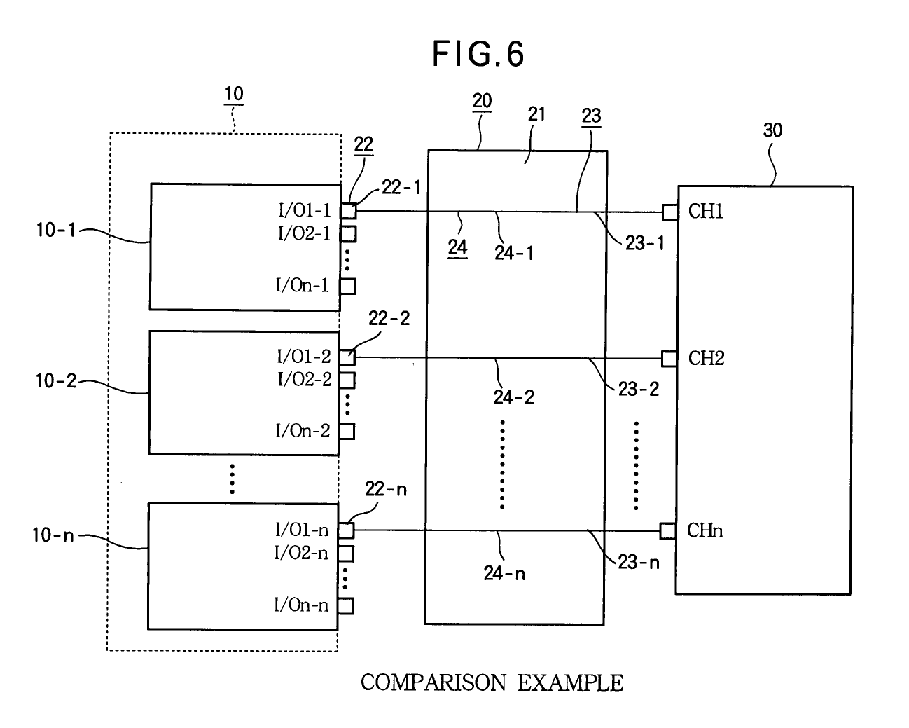

FIG. 6 shows a test apparatus for testing a semiconductor device using a probe card according to Comparison Example.

The test apparatus includes a probe card 20 and a tester 30 for testing semiconductor devices 10-1 to 10-n formed on a wafer 10. The semiconductor devices 10-1 to 10-n include internal circuits 11, BIST circuits 12 having the self-test function of the internal circuits 11, first I/O terminals 1-1, 1-2 . . . 1-n connected to the BIST circuits 12 and used for the self-test, second I/O terminals 2-1 to n-1, 2-2 to 2-n . . . 3-n to n-n connected to the internal circuits 11 and used for the normal-mode test.

The probe card 20 of Comparison Example includes a probe card substrate 21. Probe needles 22 (22-1, 22-2 . . . 22-n) are provided on the probe card substrate 21 for contact with the first I/O terminals 1-1 to 1-n of the semiconductor devices 10-1 to 10-n. Connection terminals (23-1, 23-2 . . . 23-n) are provided on the probe card substrate 21 so as to be connectable to channels CH1 to CHn of the tester 30. Connection wirings 24 (24-1, 24-2 . . . 24-n) are provided on the probe card substrate 21 so as to connect the probe needles 22 (22-1, 22-2 . . . 22-n) to the connection terminals 23 (23-1, 23-2 . . . 23-n).

The probe card 20 according to Comparison Example has neither jumper cables 55-2 to 55-n (see FIG. 1) nor the wiring conversion board 59 (see FIG. 5). In other words, the probe card 20 is configured to only connect the first I/O terminals 1-1 to 1-n of the semiconductor devices 10-1 to 10-n to the channels CH1 to CHn of the tester 30.

The self-test is performed as described in the first and second embodiments.

If any of the semiconductor devices 10-1 to 10-n is found to be defective in the self-test, the normal-mode test is performed to thereby determine a defective part of the semiconductor device. However, since the probe card 20 does not connect the second I/O terminals 2-1 to n-n of the semiconductor devices 10-1 to 10-n to the channels of the tester 30, it is necessary to use an exclusive probe card for the normal-mode test, which connects the second I/O terminals 2-1 to n-n of the semiconductor devices 10-1 to 10-n to the channels of the tester 30. However, it is inconvenient to use two types of probe cards.

In contrast, according to the above described first and second embodiments of the present invention, due to the provision of the jumper cables 55-2 to 55-n (see FIG. 1) or the wiring conversion board 59 (see FIG. 5) as second connection wirings, the self-test and the normal-mode test can be performed using the same probe card 50. In other words, it is not necessary to use an exclusive probe card for the normal-mode test. Thus, according to the first and second embodiments, it becomes possible to enhance convenience of the test for examining the quality of the semiconductor devices.

While the preferred embodiments of the present invention have been illustrated in detail, it should be apparent that modifications and improvements may be made to the invention without departing from the spirit and scope of the invention as described in the following claims.

What is claimed is:

1. A test method of a semiconductor device using a probe card,
the semiconductor device comprising an internal circuit, a self-test circuit having a function to test the internal circuit, a first signal terminal for a self-test of the internal circuit and a second signal terminal for a normal-mode test of the internal circuit,
the probe card comprising:
a probe card substrate;
a first probe needle provided on the probe card substrate for contact with the first signal terminal of the semiconductor device;
a second probe needle provided on the probe card substrate for contact with the second signal terminal of the semiconductor device;
a connection terminal provided on the probe card substrate and being connectable to a tester,
a first connection wiring provided on the probe card substrate so as to connect the first probe needle to the connection terminal, and
a second connection wiring provided on the probe card substrate so as to connect the second probe needle to the first connection wiring,
the test method comprising the steps of:
performing a self-test to thereby examine a quality of the semiconductor device by connecting the first probe needle to the first signal terminal of the semiconductor device and by using the tester connected to the connection terminal, and
performing a normal-mode test to thereby examine a quality of the semiconductor device by connecting the second probe needle to the second signal terminal of the semiconductor device and by using the tester connected to the connection terminal that is connected to the second signal terminal via the first connection wiring and the second connection wiring.

2. The test method according to claim 1, wherein the self-test is performed on a plurality of the semiconductor devices, and the normal-mode test is performed on at least one of the plurality of the semiconductor devices which has been determined to be defective in the self-test.

3. The test method according to claim 1, wherein the second connection wirings are composed of jumper cables.

4. The test method according to claim 1, wherein the second connection wirings are provided in a wiring conversion board connected to the probe card substrate.
